(19) United States
(12) Patent Application Publication
(10) Pub. No.: US 2012/0273882 A1
(43) Pub. Date: Nov. 1, 2012

(54) SHALLOW-TRENCH CMOS-COMPATIBLE SUPER JUNCTION DEVICE STRUCTURE FOR LOW AND MEDIUM VOLTAGE POWER MANAGEMENT APPLICATIONS

(76) Inventor: PERUMAL RATNAM, Fremont, CA (US)

(21) Appl. No.: 13/095,546

(22) Filed: Apr. 27, 2011

(51) Int. Cl. H01L 29/78; H01L 21/336

(52) U.S. Cl. 257/339; 438/286; 257/E29.256; 257/E21.409

(57) ABSTRACT

A novel lateral super junction device compatible with standard CMOS processing techniques using shallow trench isolation is provided for low- and medium-voltage power management applications. The concept is similar to other lateral super junction devices having N- and P-type implants to deplete laterally to sustain the voltage. However, the use of shallow trench structures provides the additional advantage of reducing the Rdson without the loss of the super junction concept and, in addition, increasing the effective channel width of the device to form a “FINFET” type structure, in which the conducting channel is wrapped around a thin silicon “fin” that forms the body of the device. The device is manufactured using standard CMOS processing techniques with the addition of super junction implantation steps, and the addition of polysilicon within the shallow trench structures to form fin structures.

### BACKGROUND OF THE INVENTION

1. Field of the Invention

The present invention relates semiconductor power management structures, and more specifically to laterally diffused super junction MOSFET devices for power management in the 15 V to 40 V range.

2. Description of Related Art

Laterally diffused metal oxide semiconductor (LDMOS) structures are known in the art and used to manufacture transistors for power amplifiers, RF circuits, and many other applications. LDMOS transistors are generally fabricated using an epitaxial silicon layer on a more highly doped silicon substrate and are characterized by a large source-drain breakdown voltage, usually exceeding 60 volts. Thus, they have been the devices of choice for most of the monolithic low voltage and medium voltage power management applications due to the relative simplicity of the structures and their reasonable cost.

Super junction devices are also known in the art. A super junction device is characterized by multiple alternating regions of N- and P-type doped semiconductor. When the alternating regions are relatively narrow and the net doping in both types of material is approximately equal, it is possible to deplete the region at a relatively low voltage. This makes the alternating N- and P-type layers behave somewhat like an intrinsic semiconductor layer and results in a high breakdown voltage. The use of super junction devices has been largely confined to higher voltage applications (>200V) in most industrial applications. This is primarily due to the relative complexity of super junction device scaling and the cost of manufacturing. Generally, the super junction devices are vertical (source at the top surface of the silicon substrate and drain at the bottom) and are manufactured using either selective epitaxial or deep implants, or similar techniques. This leads to a relatively high cost for this class of devices. However, in recent years, there have been attempts to make medium voltage (<100V) lateral super junction devices. However, the drain-source on resistance (Rdson) of this kind of device has generally been found to be no lower than that of standard LDMOS of similar breakdown voltage.

Accordingly, it would be desirable to achieve an LDMOS device suitable for large scale integration having a high breakdown voltage while also achieving a low Rdson and a reasonable manufacturing cost.

### SUMMARY OF THE INVENTION

The invention is directed to a novel lateral super junction device compatible with standard CMOS processing techniques using shallow trench isolation. The concept is similar to other lateral super junction devices having N- and P-type implants to deplete laterally to sustain the voltage. However, the use of shallow trench structures provides the additional advantage of reducing the Rdson without the loss of the super junction concept and, in addition, increasing the effective channel width of the device to form a “FINFET” type structure, in which the conducting channel is wrapped around one or more thin silicon “fins” that form the body of the device.

In a first embodiment of device according to the present invention, A laterally diffused metal oxide semiconductor (LDMOS) device includes a silicon substrate; a plurality of shallow trenches etched within the silicon substrate; a P-type super junction implant in the silicon substrate located adjacent to a base of each of the plurality of shallow trenches etched within the silicon substrate; an N-type drift implant in the silicon substrate located adjacent to the P-type super junction implant and between the plurality of shallow trenches within the silicon substrate; an insulating layer at least partially filling each of the plurality of shallow trenches within the silicon substrate; an additional insulating layer located on the surface of the silicon substrate and between the plurality of shallow trenches and configured as gate insulator; and a conducting layer at least partially filling the plurality of shallow trenches within the silicon substrate and also extending above the gate insulator and configured as a gate electrode.

The insulating layers may comprise any insulating material known in the art, including silicon nitride, silicon oxide, hafnium oxide, aluminum oxide, or other materials known and used in the field of semiconductor manufacturing. The conducting layer may comprise any conductive material known in the art, including polysilicon, aluminum, tungsten, titanium nitride, tantalum nitride, or any other conducting material known and used in the field of semiconductor manufacturing.

An additional embodiment may further include a first N+ implant region within the silicon substrate and adjacent to the gate electrode and configured to form a source connection; and a second N+ implant region within the silicon substrate and located on an opposite side of the gate electrode from the first N+ implant region and configured to form a drain connection.

In some embodiments, the LDMOS device includes two shallow trenches located beneath the conductive layer.

In some embodiments, the LDMOS device includes polysilicon or other conductive material within the plurality of shallow trenches that is configured as a plurality of fins of device body material within a semiconducting channel formed in the silicon substrate.

In certain embodiments, the LDMOS device includes a plurality of shallow trenches that have a depth of approximately 0.4 micrometers, a width of approximately 0.2 micrometers and a spacing of approximately 0.6 micrometers, although other dimensions and spacings are also possible.

A method of manufacturing an LDMOS device in accordance with an embodiment of the present invention includes the steps of etching a plurality of shallow trenches within the silicon substrate; implanting a P-type super junction region in the silicon substrate at a base of each of the plurality of shallow trenches; growing an oxide layer that at least partially fills the plurality of shallow trenches within the silicon substrate; implanting an N-drift super junction layer in the silicon substrate between the plurality of shallow trenches and adjacent to each of the P-type super junction regions at the base of each of the plurality of shallow trenches; masking the oxide layer to cover at least a portion of the oxide layer that at least partially fills the plurality of shallow trenches within the silicon substrate; etching the oxide layer to remove at least a portion of the oxide layer that is not covered in the masking step; growing an additional oxide layer configured as a gate oxide; depositing a polysilicon layer such that it at least partially fills the plurality of trenches and also covers the additional oxide layer to form a gate electrode; forming a source contact adjacent to a first side of the polysilicon gate electrode; and forming a drain contact on a second side of the polysilicon gate electrode opposite from the source electrode.

In some embodiments, the method of manufacture further includes a step of growing an additional oxide layer that further comprises growing oxide within the plurality of shallow trenches.

In some embodiments, the method of manufacture further includes forming a minimum of two shallow trenches in the silicon substrate, although other numbers of trenches are possible.

In some embodiments, the step of etching the plurality of shallow trenches within the silicon substrate includes etching the plurality of shallow trenches to a depth of approximately 0.4 micrometers and to a width of approximately 0.2 micrometers. And in some embodiments, the step of etching the plurality of shallow trenches within the silicon substrate comprises etching the plurality of shallow trenches such that they have a spacing of approximately 0.6 micrometers.

In an alternative embodiment of an LDMOS device in accordance with the present invention, an additional field oxide region is formed adjacent to the oxide at least partially filling the shallow trench structures. A polysilicon or other conductive field plate is formed over the additional field oxide structure such that the conductive field plate is approximately one to two micrometers from the terminus of the p-type super junction implant.

A more complete understanding of a lateral super junction device and method for manufacturing it will be afforded to those skilled in the art, as well as a realization of additional advantages and objects thereof, by a consideration of the following detailed description of the preferred embodiment. Reference will be made to the appended sheets of drawings, which will first be described briefly.

### BRIEF DESCRIPTION OF THE DRAWINGS

FIG. 1 is three-dimensional drawing of a shallow trench super junction device according to an embodiment of the present invention;

FIG. 2 is another three-dimensional drawing of a shallow trench super junction device in accordance with an embodiment of the invention showing the P-type super junction implant regions and the N+ source and drain implants;

FIG. 3 is a plot of simulation results comparing the Rdson of a shallow trench super junction device in accordance with an embodiment of the present invention to that of a standard LDMOS device;

FIG. 4 is a plot of simulation results of the breakdown voltage of a shallow trench super junction device in accordance with an embodiment of the present invention;

FIG. 5 is a plot of simulation results of the breakdown voltage of a standard LDMOS device;

FIG. 6 is a flowchart providing an exemplary manufacturing flow for a shallow trench super junction device in accordance with an embodiment of the present invention;

FIG. 7 is a drawing illustrating the P-type super junction trench implant regions in accordance with an embodiment of the present invention;

FIG. 8 is a drawing illustrating the P-type body implant and N-type drift implant region in accordance with an embodiment of the present invention;

FIG. 9 is a drawing illustrating the oxide layers remaining in the shallow trench structures after etching in accordance with an embodiment of the present invention;

FIG. 10 is a drawing illustrating the polysilicon processing steps in accordance with an embodiment of the present invention;

FIG. 11 is a drawing of a completed shallow trench super junction device in accordance with an embodiment of the present invention;

FIG. 12 is a drawing of an alternative embodiment of a super junction device in accordance with the present invention;

FIG. 13 is a drawing of the oxide structure of an alternative embodiment of a super junction device formed according to the present invention; and

FIG. 14 is a drawing of an alternative embodiment of a super junction device, according to the present invention, illustrating a polysilicon field plate located in proximity to a polysilicon gate layer.

### DETAILED DESCRIPTION OF THE PREFERRED EMBODIMENT

The present invention provides a novel super junction LDMOS device for power management applications in the 15 to 40 volt range. The Rdson of this super junction device is simulated using 3D process/device simulators and exhibits a resistance that is 30 to 40% lower than a standard LDMOS structure with similar dimensions. The breakdown voltage at Vgs=0 (BVdss) for an embodiment of a device in accordance with the present invention is about 30 volts, compared to a standard LDMOS of the same size having a BVdss of about 22 volts. The breakdown voltage at a gate-source voltage of 5 volts (BVsoa) is about 20 volts compared to about 14 volts for a standard LDMOS device of the same size.

A preferred embodiment of a device in accordance with the present invention relates to a novel lateral super junction device compatible with standard CMOS processing techniques using shallow trench isolation. The concept is similar to other lateral super junction devices having a N- and P-type implants to deplete laterally to sustain the voltage. However, the use of shallow trench structures provides the additional advantage of reducing the Rdson without the loss of the super junction concept and, in addition, increasing the effective channel width of the device to form a “FINFET” type structure, in which the conducting channel is wrapped around one or more thin silicon “fins” that form the body of the device.

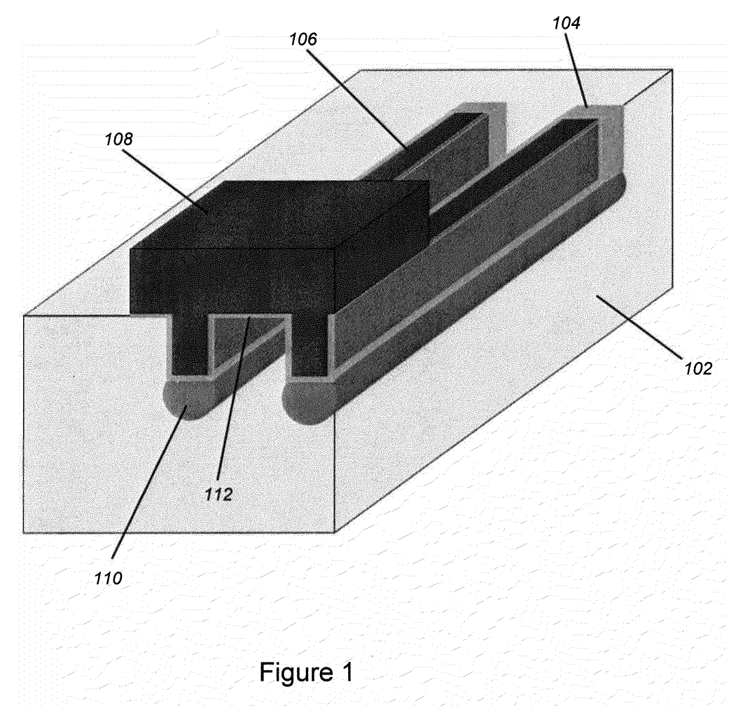

FIG. 1 is a three-dimensional drawing of a shallow-trench super junction device in accordance with an embodiment of the present invention. For clarity, the N+ source implant and P-type body implants are not shown. In this figure, the source is at the front and the drain is at the back of the structure. Visible in the figure are the shallow trench structures, e.g., 104, filled first with oxide, and then with polysilicon, as shown at 106. The gate structure 108 is also formed from polysilicon. The oxide also extends under the gate polysilicon 108 to form the gate oxide 112. The shallow trenches 104 are formed in a well of N-type material 102. At the bottom of the shallow trenches are P-type super junction implant regions 110. An N-Drift implant is located in between the shallow trenches and the P-type super junction implants but is not shown for clarity.

Although this embodiment is described as employing oxide insulating layers and polysilicon conducting layers, other materials may also be used. For example, the insulating layers may comprise any insulating material known in the art, including silicon nitride, silicon oxide, hafnium oxide, aluminum oxide, or other materials known and used in the field of semiconductor manufacturing. Similarly, the conducting layer may comprise any conductive material known in the art, including polysilicon, aluminum, tungsten, titanium nitride, tantalum nitride, or any other conducting material known and used in the field of semiconductor manufacturing.

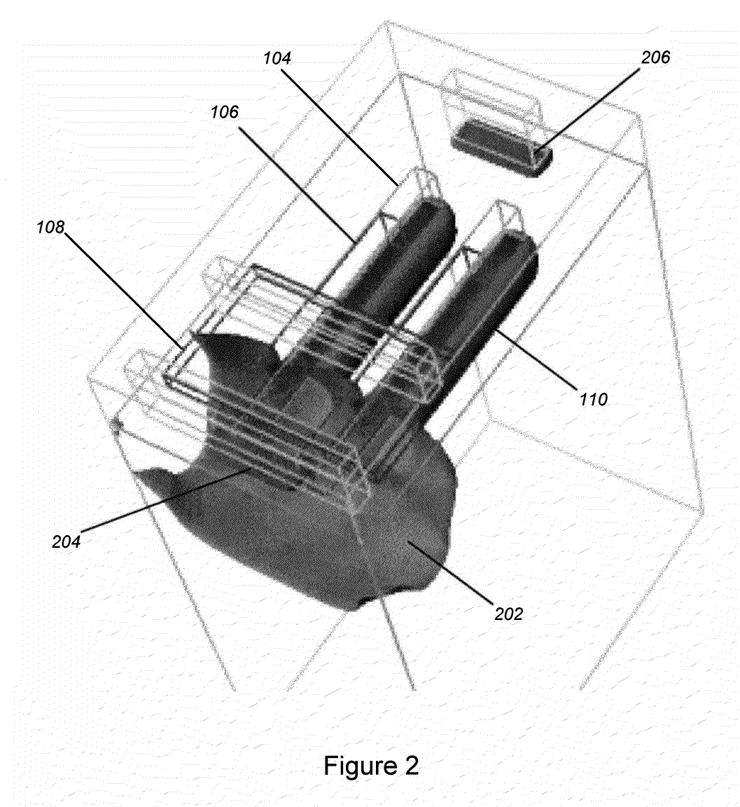

FIG. 2 is another three-dimensional drawing of a shallow shallow-trench super junction device in accordance with an embodiment of the present invention. In this figure, the device from FIG. 1 is again illustrated, but certain layers are hidden or rendered as wire frames in order to improve clarity. The P-type super junction implant regions 110 can still be seen in this figure. In addition, the P-type body implant region 202 is visible. Also visible in this figure are the N+ implants at the source and drain, 204, and 206, respectively. The polysilicon gate 108 is visible in wire frame, as are the shallow trenches filled with oxide 104 and the shallow trenches filled with polysilicon 106.

As can be seen in FIGS. 1 and 2, The N-type LDMOS super junction is made between two shallow trench regions 104 by performing a p-type implantation inside the shallow trench (see elements 110 of FIGS. 1 and 2) and growing a thin oxide 104 and filling the shallow trench with the gate polysilicon 106. The N-type drift region between these shallow trenches gets fully depleted (when the diodes underneath the shallow trench are reverse biased) to form a super junction. The MOS gate formed by shallow trench side wall regions helps to add the super junction effect. In addition, the gate poly 106 inside the shallow trench creates a FINFET structure, producing a reduction in Rdson. Thus, the Rdson of the shallow trench super junction is much lower than that of a standard super junction formed with similar dimensions. In addition, the shallow trench structure provides breakdown enhancement similar to that of a regular lateral super junction. The device shown in FIGS. 1 and 2 thus achieves both a lower Rdson (FINFET effect) and higher BVdss (super junction effect) within a single device.

Computer simulations were carried out for a shallow trench super junction device according to an embodiment of the invention using the 3D process simulation tool Victorycell from Silvaco and the3D device simulation toolAtlas3D. The geometry simulated is consistent with that shown in FIG. 2, described above. In the simulations described further below, the shallow trench width was set to 0.2 um, the depth to 0.4 um, and the spacing to 0.6 um, based on 2-D simulations, but other dimensions are possible. The device is modeled in a DNWell, which also acts as the drain of the device.

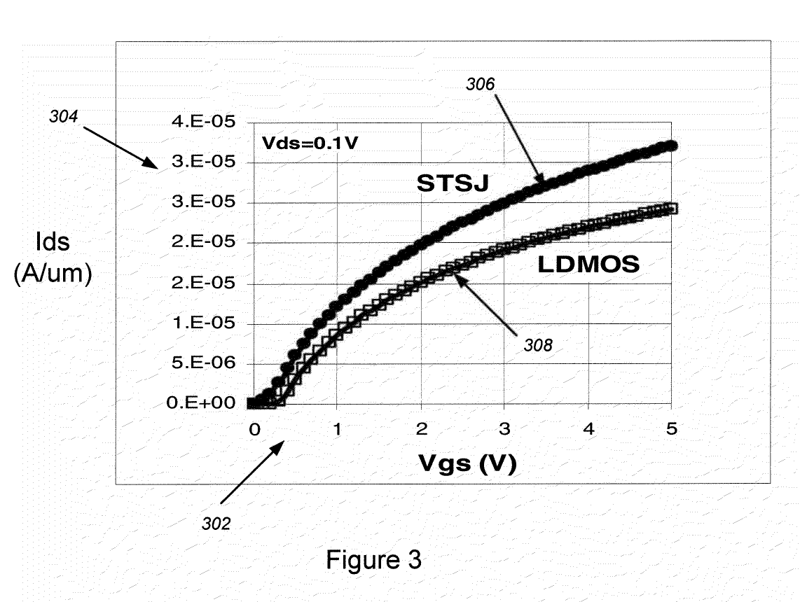

FIG. 3 is a plot of simulation results of an N-LDMOS shallow trench super junction (STSJ) device compared with a standard LDMOS device of identical size having an active gate width (top down W) of 1 um. The gate-source voltage is plotted along the horizontal axis 302, and the drain-source current is plotted along the vertical axis 304. It is readily apparent that the current through the STSJ device, plotted as curve 306, is significantly greater that that through a standard LDMOS device, plotted as curve 308. This reflects the lower Rdson achieved by the STSJ device in accordance with an embodiment of the preset invention. The effective reduction in Rdson is at least 30% for a 30V device shown in FIG. 3, compared to a standard LDMOS device of the same size at a gate-to-source voltage of 5 volts.

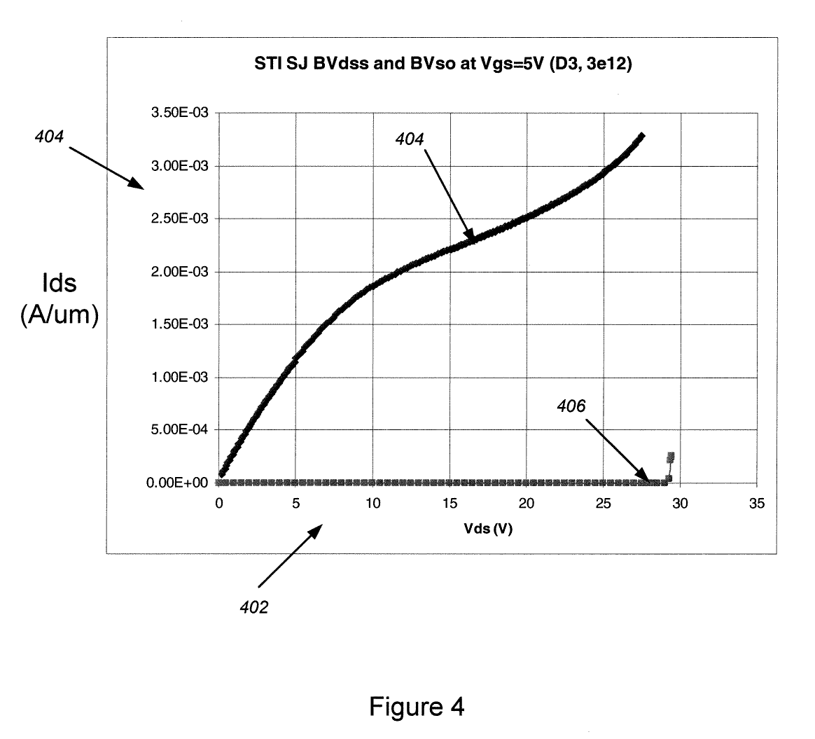

FIG. 4 is a plot of an additional simulation of an STSJ device in accordance with an embodiment of the present invention. The drain-source voltage is plotted along the horizontal axis 402, and the drain source current is plotted along the vertical axis 404. Curve 404 illustrates the breakdown voltage at a gate-source bias of 5 volts, and curve 406 shows the breakdown voltage at a gate-source voltage of 0 volts, illustrating that breakdown occurs at just under 30 volts.

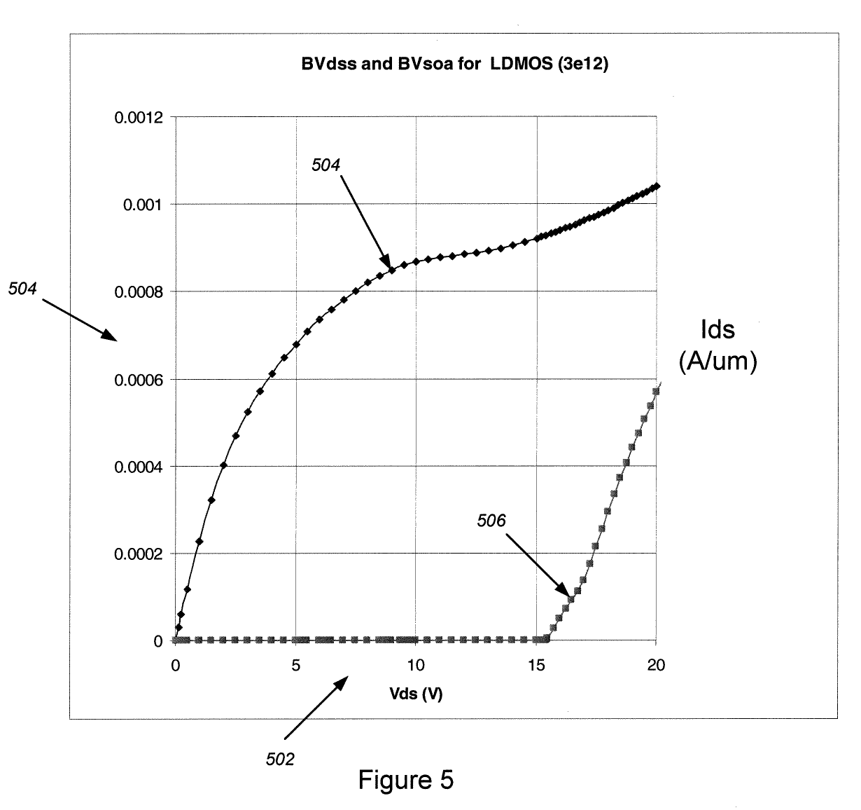

For comparison, FIG. 5 shows the same set of curves for a standard LMDOS device. The drain-source voltage is plotted along the horizontal axis 502, and the drain source current is plotted along the vertical axis 504. Curve 504 illustrates the breakdown voltage at a gate-source bias of 5 volts, and curve 506 shows the breakdown voltage at a gate-source voltage of 0 volts, illustrating that breakdown occurs at around 15 volts. Thus, the STSJ device in accordance with an embodiment of the present invention achieves better performance.

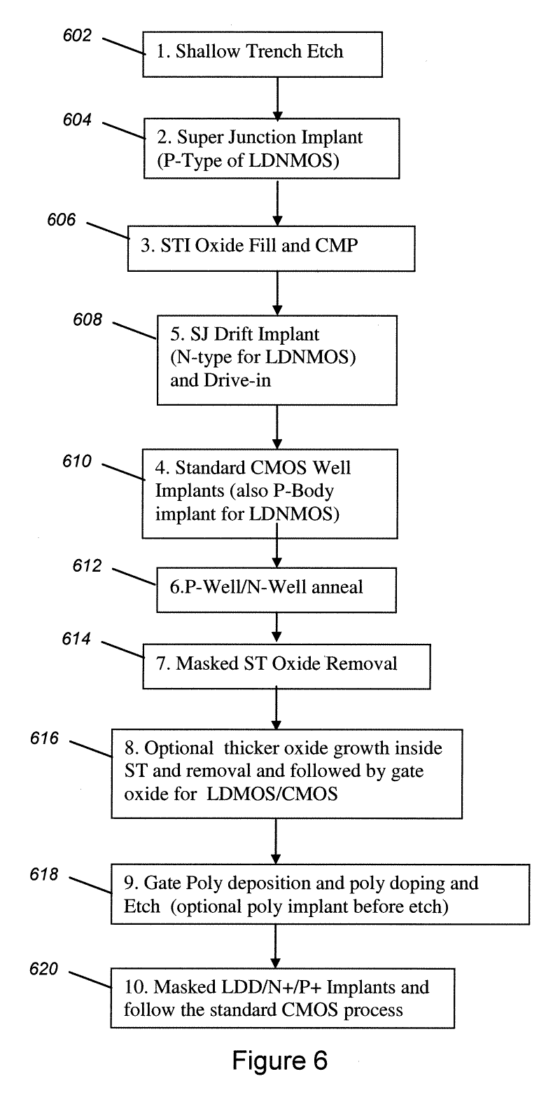

FIG. 6 is a flow chart illustrating a method of manufacturing a shallow trench super junction device in accordance with an embodiment of the present invention. The shallow trench super junction device can be integrated with existing CMOS fabrication processing techniques with feature sizes below 0.25 um and implementing shallow trench isolation. The process flow is similar to standard CMOS fabrication with the addition of a super junction implantation step (P-type in an N-well), an N-drift implantation step, and an oxide removal step inside the shallow trench followed by gate oxide growth and poly deposition. The gate mask and poly etch is similar to that of a standard CMOS/LDMOS process, except it will leave additional poly inside the shallow trench. The poly inside the shallow trench is doped either in-situ or by an additional implant.

Referring to FIG. 6, shallow trenches are etched in the substrate at step 602, and a P-type super junction is implanted at the base of the trenches in step 604. At step 606, the shallow trench is filled with an oxide insulating layer. Next, at step 608, an N-drift super junction layer is implanted, and then standard CMOS well implants are performed at step 610. The P-well and N-well implants are then annealed at step 612, followed by masking and removal of some of the oxide within the shallow trenches at step 614. At step 616, additional oxide growth within the shallow trench may occur in conjunction with the growth of the gate oxide layer. Next, gate polysilicon and shallow trench polysilicon are deposited and doped at step 618. Finally, N+ and P+ regions are implanted, and the remaining standard CMOS processing steps are performed at step 620 to complete the structure.

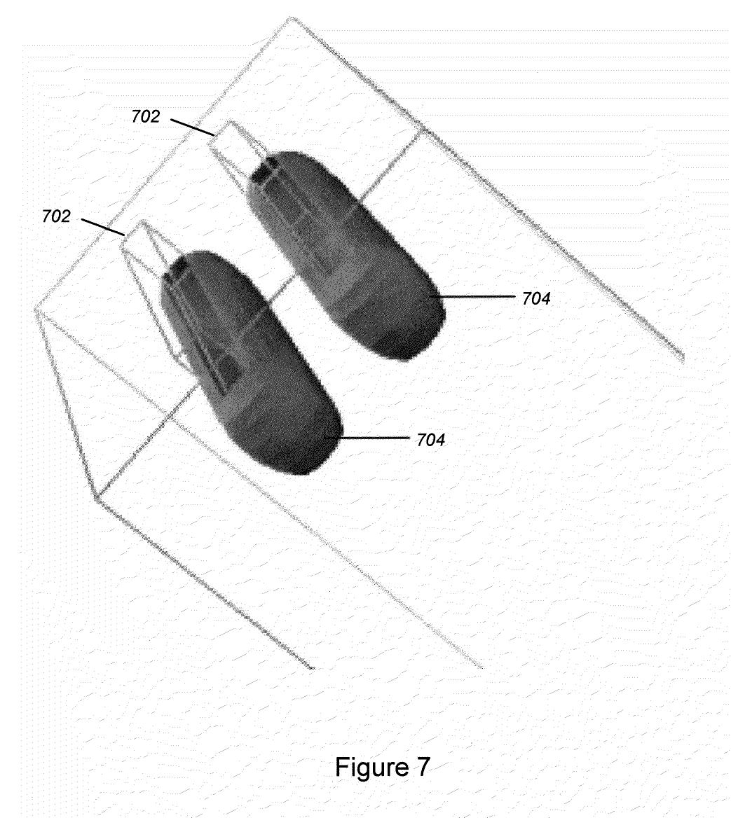

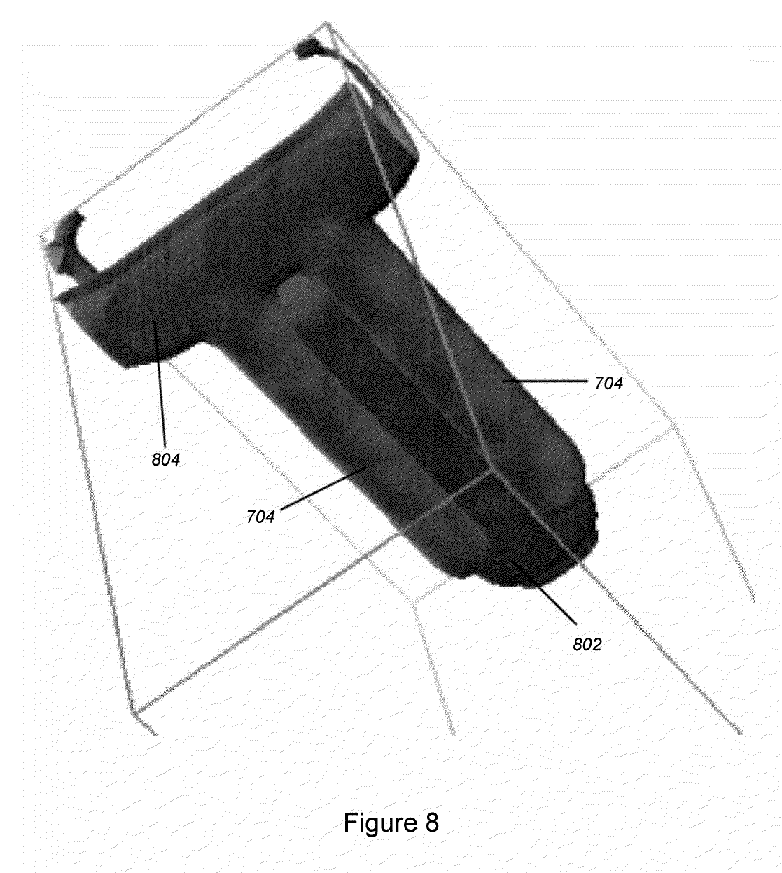

FIGS. 7 through 11 are three-dimensional drawings illustrating the manufacturing flow discussed above. FIG. 7 shows the shallow trenches 702 etched in the substrate and the P-type super junction implant regions 704 implanted in step 604 of FIG. 6. In FIG. 8, the device is shown looking from bottom up, and the P-type super junction implant regions 704 shown in the previous figure can be seen. In addition, the N-type drift implant region 802 is shown, as well as the P-type super junction body implant region 804, which are deposited in steps 608 and 610 of the flowchart in FIG. 6.

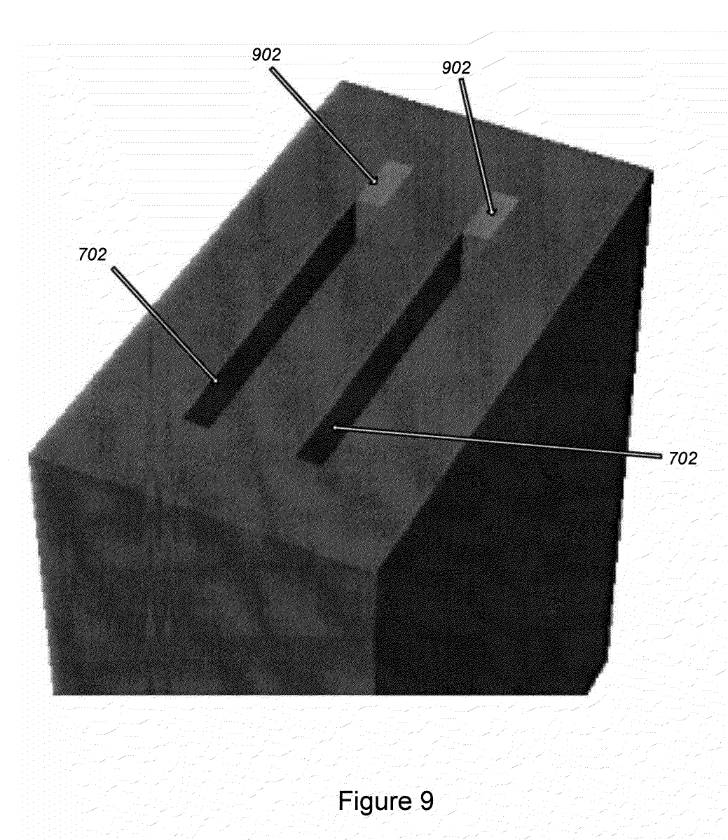

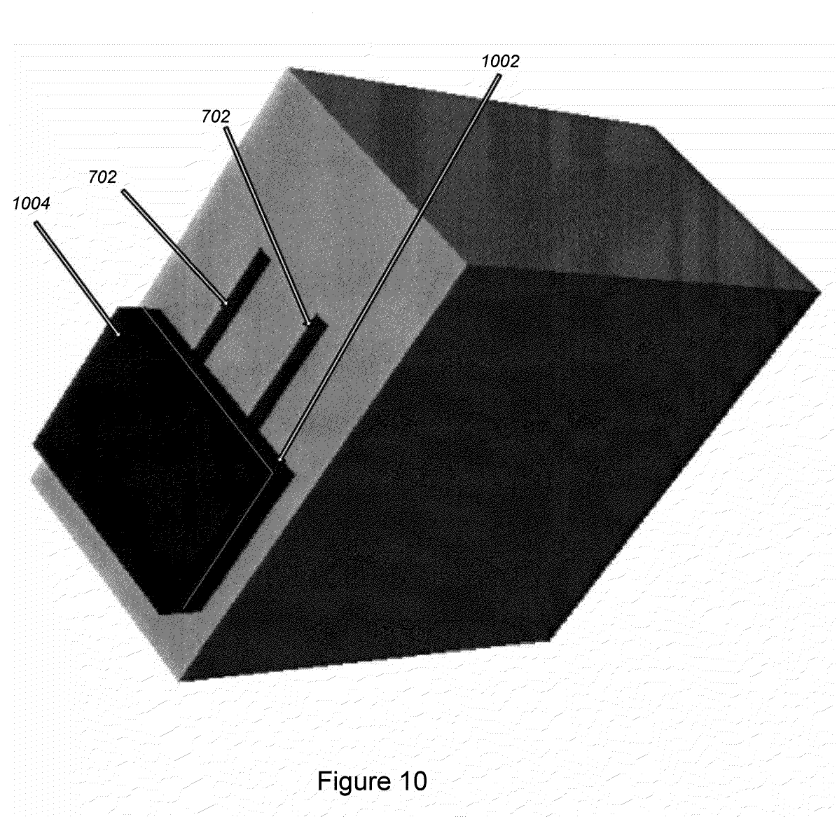

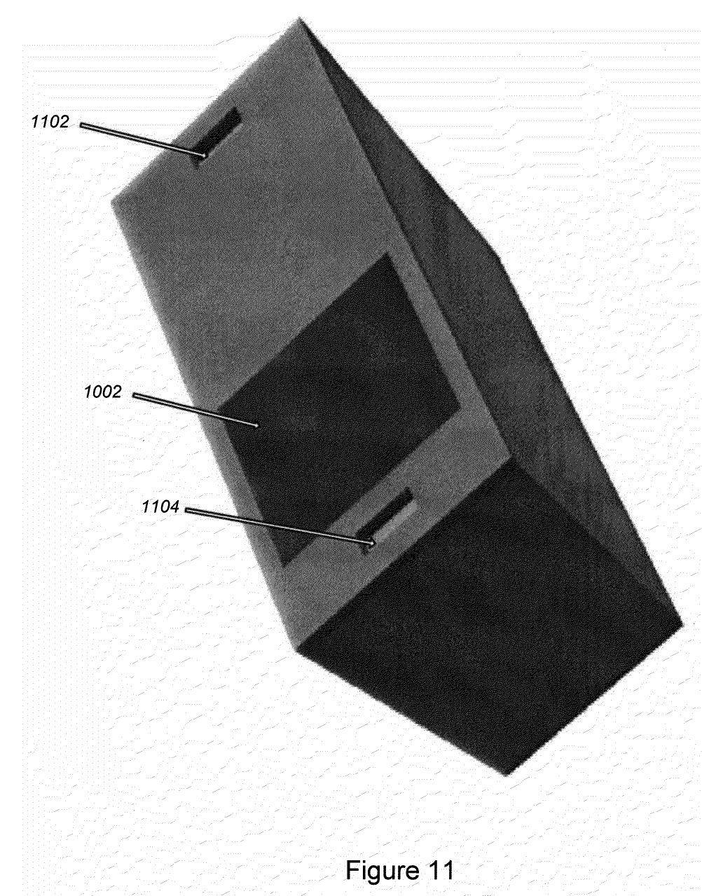

In FIG. 9, a top view of the device is shown just after the oxide masking and removal step 614 shown in the FIG. 6 flowchart. The shallow trenches 702 are visible, and the oxide remaining after etching is shown in the regions labeled 902. Next, polysilicon is deposited, filling the trenches 702 and building up the polysilicon gate. Photoresist is used to mask the gate, and the polysilicon is then etched, as described in step 618 of the FIG. 6 flowchart, leaving the structure shown in FIG. 10. Here, the polysilicon-filled shallow trenches 702 are visible. The gate polysilicon 1002 can be seen under the photoresist layer 1004. Finally, FIG. 11 shows the finished device, with the gate polysilicon 1002 exposed, and the source contact 1104 and drain contact 1102 shown.

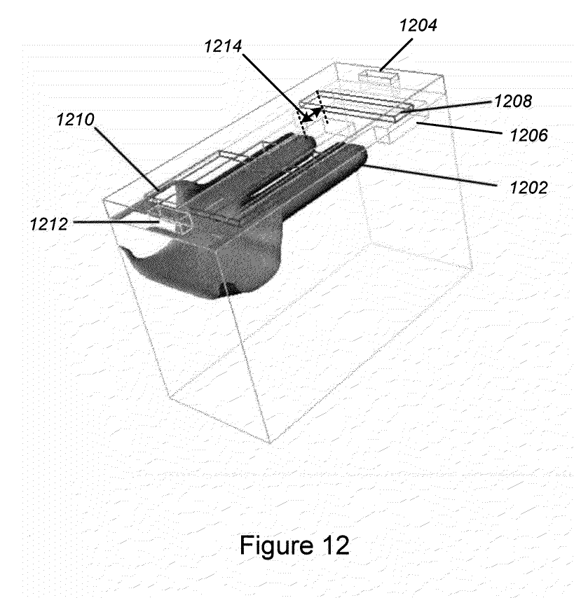

FIG. 12 depicts an alternative embodiment of shallow trench super junction structure in accordance with the present invention. The device depicted in FIG. 12 achieves an enhanced voltage breakdown threshold of approximately 60 volts. In this embodiment, a polysilicon field plate 1208 is formed above the field oxide 1206, between the drain contact 1204 and the p-type super junction implant 1202. Also depicted in FIG. 12 is the gate polysilicon 1210 and the source contact 1212. In a preferred embodiment, the polysilicon field plate set off from the terminus of the super junction implant 1202 by one to two micrometers, as depicted at 1214. The extent of the field oxide region 1206 may extend from two to five micrometers. Of course, other dimensions are possible and would fall within the scope of the present invention.

During normal operation, the polysilicon field plate 1208 is electrically tied to the gate polysilicon 1210. The polysilicon field plate 1208 thus acts as an additional gate. This has the effect of increasing the breakdown voltage of the device.

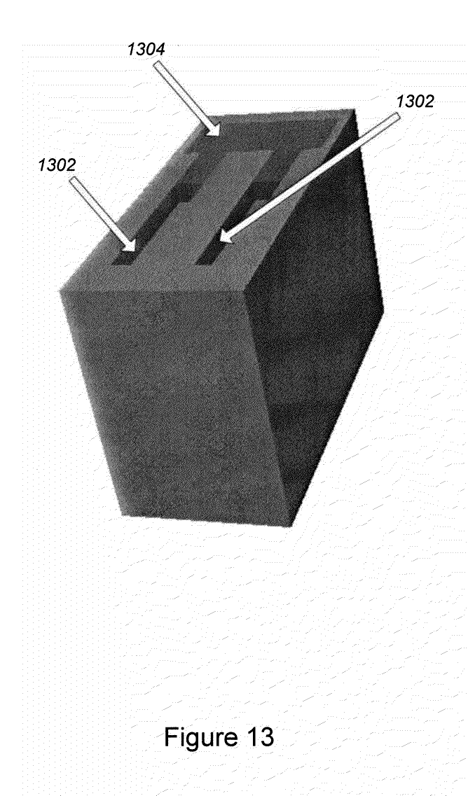

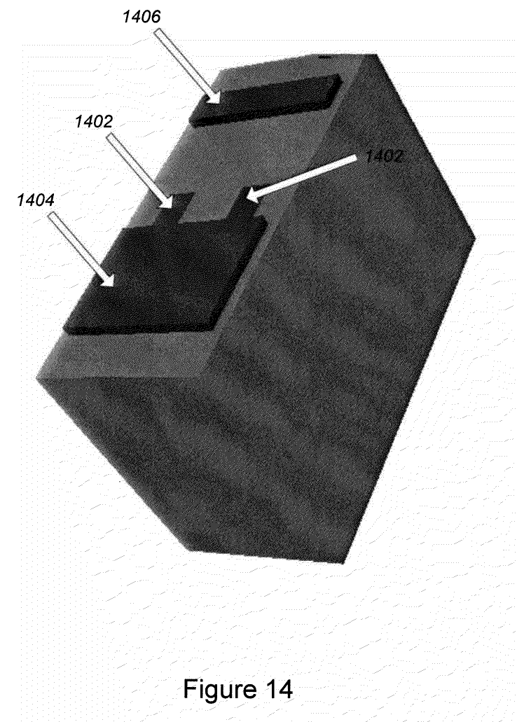

FIGS. 13 and 14 depict portions of a preferred manufacturing process for the embodiment of a shallow trench super junction that was depicted in FIG. 12. The manufacturing process generally proceeds as described above with reference to FIG. 6. However, the mask used for the deposition of the polysilicon layers is modified. FIG. 13 is a view of the device structure after the oxide cleaning step. The shallow trenches 1302 are visible, and the oxide remaining after etching is shown in the region labeled 1304. Compared with the oxide configuration shown in FIG. 9, the oxide structure of the present embodiment includes an extended region of field oxide 1304 beyond the termination of the shallow trenches 1302.

Next, polysilicon is deposited, filling the trenches 1302 and building up the polysilicon gate. Photoresist is used to mask the gate, and the polysilicon is then etched, leaving the structure shown in FIG. 14. Here, the polysilicon-filled shallow trenches 1402 are visible. The gate polysilicon layer 1404 is formed above the trenches, and the additional polysilicon field plate 1406 is visible.

While the above description has illustrated certain exemplary structures and manufacturing processes for shallow trench super junction LDMOS devices in accordance with embodiments of the present invention, the invention is not limited to any one particular embodiment. Variations to the processing steps and geometries of the device structures are possible and would fall within the scope and spirit of the present invention. For example, although the structures illustrated depict a device comprising two shallow trenches, other numbers of trenches are possible and would also fall within the scope of the present invention. Similarly, although a trench depth of 0.4 um, a width of 0.2 um, and a spacing of 0.6 um was illustrated, other trench depths and spacing values are also possible according to the needs of particular applications. Likewise, although one embodiment described above depicted a polysilicon field plate formed approximately one to two micrometers from the terminus of the shallow-trench super-junction structure, other distances, both greater and lesser, are also possible and would fall within the scope of the present invention. The invention is solely defined by the following claims.

What is claimed is:

1. A laterally diffused metal oxide semiconductor (LDMOS) device including:
a silicon substrate;
a plurality of shallow trenches etched within the silicon substrate;
a P-type super junction implant in the silicon substrate located adjacent to a base of each of the plurality of shallow trenches etched within the silicon substrate;
an N-type drift implant in the silicon substrate located adjacent to the P-type super junction implant and between the plurality of shallow trenches within the silicon substrate;
an insulating layer at least partially filling each of the plurality of shallow trenches within the silicon substrate;
an additional insulating layer located on the surface of the silicon substrate and between the plurality of shallow trenches and configured as a gate insulator; and
a conducting layer at least partially filling the plurality of shallow trenches within the silicon substrate and also extending above the gate insulator and configured as a gate electrode.

2. The LDMOS device of claim 1, wherein:
the insulating layer and the additional insulating layer comprise materials selected from the set comprising silicon nitride, silicon oxide, hafnium oxide, and aluminum oxide; and
the conducting layer comprises a material selected from the set comprising polysilicon, aluminum, tungsten, titanium nitride, and tantalum nitride.

3. The LDMOS device of claim 1, further comprising:
a first N+ implant region within the silicon substrate and adjacent to the gate electrode and configured to form a source connection; and
a second N+ implant region within the silicon substrate and located on an opposite side of the gate electrode from the first N+ implant region and configured to form a drain connection.

4. The LDMOS device of claim 1, wherein the device includes two shallow trenches located beneath the gate electrode layer.

5. The LDMOS device of claim 1, wherein the conducting layer within the plurality of shallow trenches is configured as a plurality of fins of device body material within a semiconducting channel formed in the silicon substrate.

6. The LDMOS device of claim 1, wherein:
a depth of the plurality of shallow trenches is approximately equal to 0.4 micrometers; and
a width of the each of the plurality of shallow trenches is approximately equal to 0.2 micrometers.

7. The LDMOS device of claim 1, wherein a spacing between adjacent ones of the plurality of shallow trenches is approximately equal to 0.6 micrometers.

8. The LDMOS device of claim 1, further comprising:
a field oxide region adjacent to said insulating layer at least partially filling each of the plurality of shallow trenches within the silicon substrate; and
a conductive field plate formed above the field oxide region.

9. The LDMOS device of claim 8, wherein the conductive field plate is spaced from the P-type super junction implant by a distance of between one and five micrometers.

10. A laterally diffused metal oxide semiconductor (LDMOS) device including:
a silicon substrate;
two shallow trenches etched within the silicon substrate;
a first P-type super junction implant in the silicon substrate located adjacent to a base of a first one of the two shallow trenches etched within the silicon substrate;
a second P-type super junction implant in the silicon substrate located adjacent to a base of a second one of the two shallow trenches etched within the silicon substrate;
an N-type drift implant in the silicon substrate located adjacent to the first and second P-type super junction implants and between the two shallow trenches within the silicon substrate;
an oxide layer at least partially filling each of the two shallow trenches within the silicon substrate;
an additional oxide layer located on the surface of the silicon substrate and between the two shallow trenches and configured as gate oxide;
a polysilicon layer at least partially filling the two shallow trenches within the silicon substrate and also extending above the gate oxide and configured as a gate electrode, wherein the polysilicon later at least partially filling the two shallow trenches forms two fins of body material within a semiconducting channel in the silicon substrate;
a first N+ implant region within the silicon substrate and adjacent to the polysilicon gate electrode and configured to form a source connection; and
a second N+ implant region within the silicon substrate and located on an opposite side of the polysilicon gate electrode from the first N+ implant region and configured to form a drain connection.

11. The LDMOS device of claim 10, wherein a depth of the two shallow trenches is approximately equal to 0.4 micrometers.

12. The LDMOS device of claim 10, wherein a spacing between the two shallow trenches is approximately equal to 0.6 micrometers.

13. The LDMOS device of claim 10, further comprising:
a field oxide region adjacent to said oxide layer at least partially filling each of the two shallow trenches within the silicon substrate; and
a polysilicon field plate formed above the field oxide region.

14. The LDMOS device of claim 13, wherein the polysilicon field plate is spaced from the first and second P-type super junction implants by a distance of between one and two micrometers.

15. A method of manufacturing a shallow trench super junction LDMOS semiconductor device in a silicon substrate, comprising the steps of:
etching a plurality of shallow trenches within the silicon substrate;
implanting a P-type super junction region in the silicon substrate at a base of each of the plurality of shallow trenches;
growing an oxide layer that at least partially fills the plurality of shallow trenches within the silicon substrate;
implanting an N-drift super junction layer in the silicon substrate between the plurality of shallow trenches and adjacent to each of the P-type super junction regions at the base of each of the plurality of shallow trenches;
masking the oxide layer to cover at least a portion of the oxide layer that at least partially fills the plurality of shallow trenches within the silicon substrate;
etching the oxide layer to remove at least a portion of the oxide layer that is not covered in the masking step;
growing an additional oxide layer configured as a gate oxide;
depositing a polysilicon layer such that it at least partially fills the plurality of trenches and also covers the additional oxide layer to form a gate electrode;
forming a source contact adjacent to a first side of the polysilicon gate electrode; and
forming a drain contact on a second side of the polysilicon gate electrode opposite from the source electrode.

16. The method of manufacturing a shallow trench super junction LDMOS semiconductor device in a silicon substrate of claim 15, wherein the step of growing an additional oxide layer further comprises growing oxide within the plurality of shallow trenches.

17. The method of manufacturing a shallow trench super junction LDMOS semiconductor device in a silicon substrate of claim 15, wherein the plurality of shallow trenches comprises two shallow trenches.

18. The method of manufacturing a shallow trench super junction LDMOS semiconductor device in a silicon substrate of claim 15, wherein the process of etching a plurality of shallow trenches within the silicon substrate comprising etching the plurality of shallow trenches to a depth of approximately 0.4 micrometers.

19. The method of manufacturing a shallow trench super junction LDMOS semiconductor device in a silicon substrate of claim 15, wherein the process of etching a plurality of shallow trenches within the silicon substrate comprising etching the plurality of shallow trenches such that they are spaced by approximately 0.6 micrometers.

20. The method of manufacturing a shallow trench super junction LDMOS semiconductor device in a silicon substrate of claim 15, wherein the process of growing an oxide layer that at least partially fills the plurality of shallow trenches within the silicon substrate further comprises growing an additional field oxide region adjacent to the oxide layer that at least partially fills the plurality of shallow trenches.

21. The method of manufacturing a shallow trench super junction LDMOS semiconductor device in a silicon substrate of claim 20, further comprising depositing a polysilicon layer such that it forms a polysilicon field plate above the additional field oxide region located adjacent to the oxide layer that at least partially fills the plurality of shallow trenches.
